(19) United States
(12) Patent Application Publication
(10) Pub. No.: US 2025/0311513 A1
(43) Pub. Date: Oct. 2, 2025

(54) Light source module and display device

(71) Applicant: CHAMP VISION DISPLAY INC., MIAO-LI COUNTY (TW)

(72) Inventors: CHIA-HUNG YU, MIAO-LI COUNTY (TW); YI-WEN LIN, MIAO-LI COUNTY (TW); CHIAO-CHIH YANG, MIAO-LI COUNTY (TW)

(21) Appl. No.: 19/077,081

(22) Filed: Mar. 12, 2025

(30) Foreign Application Priority Data
Mar. 26, 2024 (TW) 113203008

(51) Int. Cl. H10H 29/855; H01L 25/075; H10H 29/852

(52) U.S. Cl. CPC H10H 29/855; H01L 25/0753; H10H 29/852

(57) ABSTRACT

A light source module includes a substrate, a light-emitting unit, a package layer, a transparent plate, and an electromagnetic induction layer. The light-emitting unit is disposed on the substrate. The package layer is disposed on the substrate, and the package layer covers the light-emitting unit. The package layer has a surface facing away from the substrate. The transparent plate is disposed on the surface. The transparent plate has a first surface and a second surface. The first surface and the second surface are opposite to each other, and the first surface faces away from the package layer. The electromagnetic induction layer is disposed on the first surface or the second surface. A display device having the light source module is also provided.

### CROSS-REFERENCE TO RELATED APPLICATION

This application claims the priority benefit of Taiwan application (No. 113203008), filed on Mar. 26, 2024. The entirety of the above-mentioned patent application is hereby incorporated by reference herein and made a part of this specification.

### TECHNICAL FIELD

The disclosure relates to an optical module, and more particularly to a light source module, and a display device having the light source module.

### BACKGROUND

Touch function of a display device is not only able to improve operational convenience, but also provide drawing and writing functions with the development of touch technology. For example, a creator can use a stylus to draw directly on a touch screen, and the touch screen can display lines with different thicknesses based on pressure applied by the stylus to truly represent writing feel. Generally, the touch function of the display device is provided by a touch layer, and the touch layer is disposed on a back plate. In addition, the light source is usually disposed on the touch layer, and the light source is configured with a plurality of support members each with a certain height to support components located above the light source.

However, because a conventional display device has at least components such as a touch layer, a light source, and a support member, a process of assembling the display device is cumbersome and wasting lots of time. Additionally, a conventional back plate often has an uneven surface, resulting in slow or inaccurate sensing of the touch layer. In addition, a thickness of the display device is significantly increased by the support member.

The information disclosed in this “BACKGROUND” section is only for enhancement understanding of the background and therefore it may contain information that does not form the prior art that is already known to a person of ordinary skill in the art. Furthermore, the information disclosed in this “BACKGROUND” section does not mean that one or more problems to be solved by one or more embodiments of the disclosure were acknowledged by a person of ordinary skill in the art.

### SUMMARY

In order to achieve one or a portion of or all of the objects or other objects, an embodiment of the disclosure provides a light source module including a substrate, a light-emitting unit, a package layer, a transparent plate and an electromagnetic induction layer. The light-emitting unit is disposed on the substrate. The package layer is disposed on the substrate and covers the light-emitting unit. The package layer has a surface facing away from the substrate. The transparent plate is disposed on the surface. The transparent plate has a first surface and a second surface. The first surface is opposite to the second surface, and the first surface faces away from the package layer. The electromagnetic induction layer is disposed on one of the first surface and the second surface.

In order to achieve one or a portion of or all of the objects or other objects, an embodiment of the disclosure provides a display device including a display panel and the light source module. The display panel is disposed on a side of the transparent plate facing away from the package layer.

Other objectives, features and advantages of the present disclosure will be further understood from the further technological features disclosed by the embodiments of the present disclosure wherein there are shown and described preferred embodiments of this disclosure, simply by way of illustration of modes best suited to carry out the disclosure.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional diagram of a light source module in an embodiment of the disclosure;

FIG. 2 is a schematic cross-sectional diagram of a light source module in another embodiment of the disclosure;

FIG. 3 is a schematic cross-sectional diagram of a light source module in another embodiment of the disclosure;

FIG. 4 is a schematic cross-sectional diagram of a display device in an embodiment of the disclosure;

FIG. 5 is a schematic cross-sectional diagram of a display device in another embodiment of the disclosure; and

FIG. 6 is a schematic cross-sectional diagram of a display device in another embodiment of the disclosure.

### DETAILED DESCRIPTION OF PREFERRED EMBODIMENTS

In the following detailed description of the preferred embodiments, reference is made to the accompanying drawings which form a part hereof, and in which are shown by way of illustration specific embodiments in which the disclosure may be practiced. In this regard, directional terminology, such as “top,” “bottom,” “front,” “back,” etc., is used with reference to the orientation of the Figure(s) being described. The components of the present disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

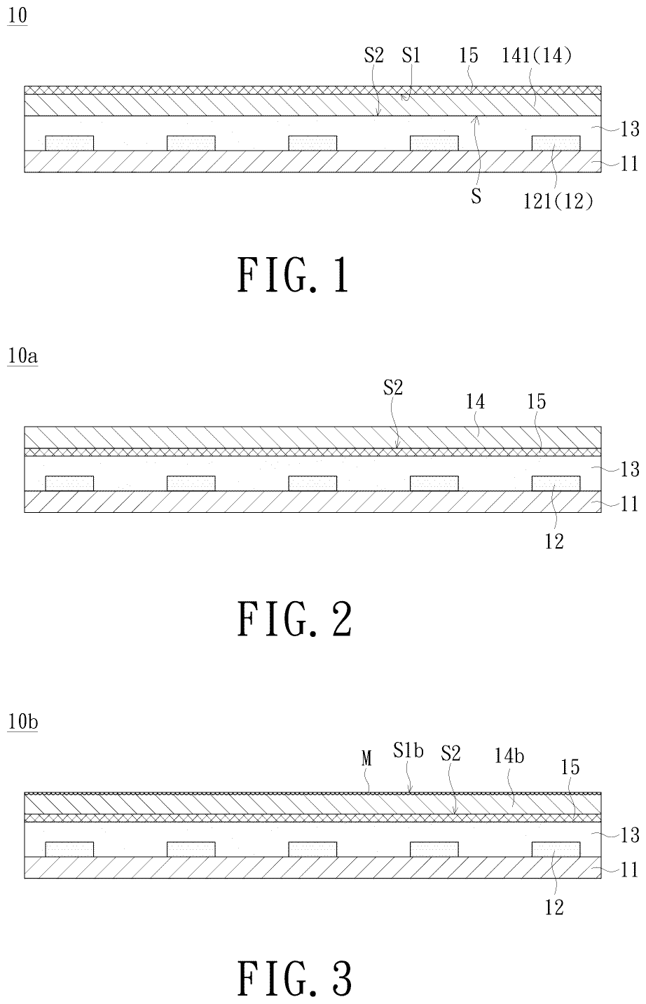

FIG. 1 is a schematic cross-sectional diagram of a light source module in an embodiment of the disclosure. Referring to FIG. 1, a light source module 10 includes a substrate 11, a light-emitting unit 12, a package layer 13, a transparent plate 14, and an electromagnetic induction layer 15. The light-emitting unit 12 is disposed on the substrate 11. The package layer 13 is disposed on the substrate 11 and covers the light-emitting unit 12. The package layer 13 has a surface S facing away from the substrate 11. The transparent plate 14 is disposed on the surface S. The transparent plate 14 has a first surface S1 and a second surface S2. The first surface S1 is opposite to the second surface S2, and the first surface S1 faces away from the package layer 13. The electromagnetic induction layer 15 is disposed on the first surface S1 or the second surface S2, and this embodiment takes the electromagnetic induction layer 15 being disposed on the first surface S1 as an example.

The substrate 11 may include a circuit board or a glass substrate. For example, the substrate 11 may include a printed circuit board (PCB) in an embodiment, and the light-emitting unit 12 is electrically connected to the printed circuit board. The substrate 11 may include the glass substrate in another embodiment, the glass substrate may be provided with a circuit, and the light-emitting unit 12 is electrically connected to the circuit.

The light-emitting unit 12 in this embodiment may include a light-emitting chip 121. The light-emitting chip 121 is disposed on the substrate 11, and the package layer 13 covers the light-emitting chip 121. Specifically, the light-emitting chip 121 is, for example, a light-emitting die that has been processed with wire bonding or surface mounted but has not been packaged. In addition, the light-emitting unit 12 includes, for example, a mini light-emitting diode (Mini LED) unit or a micro light-emitting diode (Micro LED) unit. For example, the mini light-emitting diode unit may include the light-emitting chip 121 of a mini light-emitting diode, and the micro light-emitting diode unit may include the light-emitting chip 121 of a micro light-emitting diode.

The package layer 13 may completely cover the light-emitting unit 12. Furthermore, because the light-emitting unit 12 in this embodiment is the light-emitting chip 121 that has not been packaged, the package layer 13 can directly cover the light-emitting chip 121. Therefore, the package layer 13 is not only able to protect the light-emitting chip 121 but also supported between the substrate 11 and the transparent plate 14, so that the support member in the prior art can be omitted to reduce the thickness of the light source module 10. Incidentally, the material of the package layer 13 includes, for example, epoxy or silicone, but the disclosure is not limited thereto.

The electromagnetic induction layer 15 uses, for example, electro-magnetic resonance (EMR) technology to provide a touch function in this embodiment. It should be noted that the touch sensitivity of the electromagnetic induction layer 15 is affected by the flatness of the surface. For example, the electromagnetic induction layer 15 is disposed on the back plate in the prior art; however, the surface of the back plate is uneven because of the warping of the back plate after the stamping process, which affects the touch sensitivity of the electromagnetic induction layer 15.

However, because the manufacturing process of the transparent plate 14 in this embodiment does not include the stamping or other processes with high impact force, the first surface S1 and the second surface S2 of the transparent plate 14 can be flatter than the conventional back plate, thereby being more appropriate for arranging the electromagnetic induction layer 15. Based on the above, the transparent plate 14 can significantly improve the touch sensitivity of the electromagnetic induction layer 15 compared with the conventional back plate. Particularly, the transparent plate 14 may include a glass transparent plate 141, and the first surface S1 and the second surface S2 are located on the glass transparent plate 141. In other words, the electromagnetic induction layer 15 can be disposed on the glass transparent plate 141, and because the glass transparent plate 141 has the advantage of a flat surface, the touch sensitivity of the electromagnetic induction layer 15 can be further improved.

Compared with the prior art, the light source module 10 in this embodiment uses the substrate 11 and the transparent plate 14 to sandwich the package layer 13, and the electromagnetic induction layer 15 is disposed on the transparent plate 14. Specifically, the light-emitting unit 12 can be fixed to the substrate 11 in advance, and the electromagnetic induction layer 15 can be fixed to the transparent plate 14 in advance. The transparent plate 14 fixed with the electromagnetic induction layer 15 and the substrate 11 fixed with the light-emitting unit 12 can be fixed to each other via the package layer 13 to form the light source module 10. Therefore, the substrate 11, the light-emitting unit 12, the package layer 13, the transparent plate 14, and the electromagnetic induction layer 15 are able to form an integrated structure, and the light source module 10 can be formed without the need for individual assembly, thus significantly simplifying the process of assembling the light source module 10. In addition, the first surface S1 of the transparent plate 14 has a good flatness for the electromagnetic induction layer 15 to be disposed so the touch sensitivity of the electromagnetic induction layer 15 can be improved. In addition, the package layer 13 can be supported between the substrate 11 and the transparent plate 14 so the package layer 13 can replace the support member in the prior art, thereby reducing the thickness of the light source module 10.

FIG. 2 is a schematic cross-sectional diagram of a light source module in another embodiment of the disclosure. The structure and advantages of the light source module 10a of this embodiment are similar to those in the embodiment in FIG. 1, and only the differences are described below. Referring to FIG. 2, the electromagnetic induction layer 15 can be disposed on the second surface S2. In other words, the electromagnetic induction layer 15 is sandwiched between the package layer 13 and the transparent plate 14, and therefore, the package layer 13 and the transparent plate 14 can protect the electromagnetic induction layer 15 to prevent the electromagnetic induction layer 15 from being scratched and damaged by external objects, thereby improving the yield of the light source module 10a. Similarly, because the second surface S2 has a good flatness for the electromagnetic induction layer 15 to be disposed, the touch sensitivity of the electromagnetic induction layer 15 can be improved.

FIG. 3 is a schematic cross-sectional diagram of a light source module in another embodiment of the disclosure. The structure and advantages of the light source module 10b in this embodiment are similar to those in the embodiment of FIG. 2, and only the differences will be described below. Referring to FIG. 3, the first surface S1b of the transparent plate 14b can be formed with a plurality of optical microstructures M to diffuse the light generated by the light-emitting unit 12, thereby improving the optical grade of the light source module 10b. The optical microstructures M include, for example, recessed microstructures. In addition, the shape of the optical microstructure M may be similar to a hemispherical sphere, but the specific shape of the optical microstructure M is not limited by the disclosure. Incidentally, because the electromagnetic induction layer 15 in this embodiment is disposed on the second surface S2, the second surface S2 may be a flat plane not formed with the optical microstructures M to allow the electromagnetic induction layer 15 to be disposed.

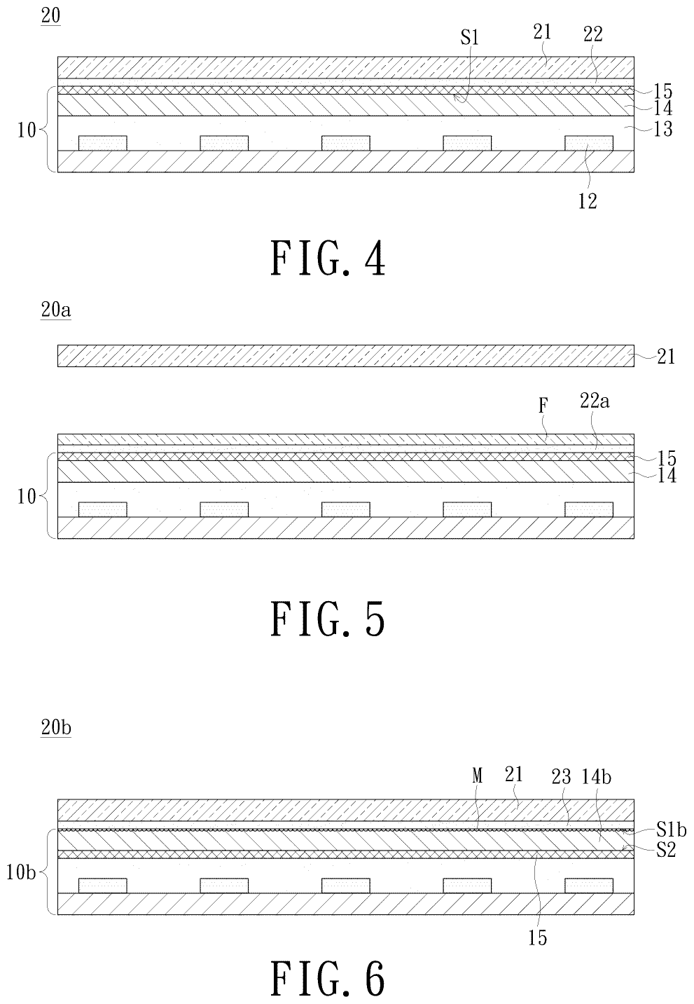

FIG. 4 is a schematic cross-sectional diagram of a display device in an embodiment of the disclosure. Referring to FIG. 4, a display device 20 includes the light source module 10 and a display panel 21. The display panel 21 is disposed on a side of the transparent plate 14 facing away from the package layer 13.

The display panel 21 can be disposed opposite to the first surface S1 to receive the light emitted by the light-emitting unit 12. For example, the electromagnetic induction layer 15 is disposed on the first surface S1 in this embodiment, and the electromagnetic induction layer 15 is located between the transparent plate 14 and the display panel 21. In addition, the display device 20 further includes, for example, a transparent glue layer 22, and the display panel 21 can be fixed to the electromagnetic induction layer 15 via the transparent glue layer 22. Furthermore, the display panel 21 can be fixed to the light source module 10 by the transparent glue layer 22 via the way of air bonding or direct bonding, which is not limited by the disclosure. Incidentally, the way of fixing the display panel 21 to the light source module 10 is not limited to adhesion, and therefore the display device 20 may not be provided with the transparent glue layer 22 in other embodiments.

Compared with the prior art, the display device 20 in this embodiment uses the light source module 10. Thus, the process of assembling the display device 20 can be simplified, the touch sensitivity can be improved, and the thickness can be reduced. The display device 20 can use the light source module 10a or 10b in other embodiments.

FIG. 5 is a schematic cross-sectional diagram of a display device in another embodiment of the disclosure. The structure and advantages of the display device 20a in this embodiment are similar to those in the embodiment in FIG. 4, and only the differences are described below. Referring to FIG. 5, the display device 20a further includes, for example, an optical film F, and the optical film F is disposed between the electromagnetic induction layer 15 and the display panel 21. Specifically, the optical film F may include a diffuser, but the disclosure is not limited thereto. In addition, the transparent glue layer 22a can be disposed on the side of the electromagnetic induction layer 15 facing away from the transparent plate 14 in this embodiment, and the transparent glue layer 22a is located between the optical film F and the electromagnetic induction layer 15. In other words, the optical film F can be fixed to the electromagnetic induction layer 15 by the transparent glue layer 22a. Moreover, the transparent glue layer 22a directly contacts with, for example, the electromagnetic induction layer 15 and the optical film F so that the optical film F is directly fixed to the electromagnetic induction layer 15 through the transparent glue layer 22a. However, the way of fixing the optical film F is not limited by the disclosure. The transparent glue layer 22a may include liquid optical clear resin (OCR) or optically clear adhesive (OCA) in this embodiment, but other embodiments are not limited thereto.

FIG. 6 is a schematic cross-sectional diagram of a display device in another embodiment of the disclosure. The structure and advantages of the display device 20b in this embodiment are similar to those of the embodiment in FIG. 5, and only the differences are described below. Referring to FIG. 6, the electromagnetic induction layer 15 is disposed on the second surface S2, and the first surface S1b can be formed with a plurality of optical microstructures M. In other words, the display device 20b can use the light source module 10b of FIG. 3. As described above, the transparent plate 14b is able to diffuse light via the optical microstructures M so the optical film may be omitted from the display device 20b, thereby further reducing the thickness of the display device 20b. On the other hand, the display device 20b further includes a solid transparent glue layer 23, for example. The first surface S1b has a plurality of recessed microstructures to form the optical microstructures M, and the solid transparent glue layer 23 is disposed on the first surface S1b. Specifically, the solid transparent glue layer 23 is in a solid state so the solid transparent glue layer 23 does not flow into the optical microstructures M when the solid transparent glue layer 23 is fixed to the first surface S1b. Therefore, the display panel 21 can be fixed to the first surface S1b by the solid transparent glue layer 23, and the solid transparent glue layer 23 can also avoid damaging the optical effect of the optical microstructures M. The solid transparent glue layer 23 includes, for example, a double-sided tape in this embodiment, and the double-sided tape may include optically clear adhesive (OCA). Similarly, the display panel 21 can be fixed to the first surface S1b by the air bonding or the direct bonding. Similarly, the solid transparent glue layer 23 can directly contact with the first surface S1b and the display panel 21; that is, the display panel 21 is directly adhered to the first surface S1b by the solid transparent glue layer 23.

In summary, the light source module and the display device in the embodiments of the invention have at least one of the following advantages. The light source module of the disclosure uses the substrate and the transparent plate to sandwich the package layer, and the electromagnetic induction layer is disposed on the transparent plate. Specifically, the light-emitting unit can be fixed to the substrate in advance, and the electromagnetic induction layer can be fixed to the transparent plate in advance. The transparent plate fixed with the electromagnetic induction layer and the substrate fixed with the light-emitting unit can be fixed to each other through the package layer to form the light source module. Therefore, the substrate, the light-emitting unit, the package layer, the transparent plate and the electromagnetic induction layer form an integrated structure, and the light source module can be formed without the need for individual assembly, thus significantly simplifying the process of assembling the light source module. In addition, the first surface and the second surface of the transparent plate have a good flatness for the electromagnetic induction layer to be disposed so the touch sensitivity of the electromagnetic induction layer can be improved. In addition, the package layer can be supported between the substrate and the transparent plate so the package layer can replace the support member in the prior art, thereby reducing the thickness of the light source module. The display device of the disclosure uses the light source module, so the display device is able to simplify assembly process, improve touch sensitivity and reduce a thickness.

The foregoing description of the preferred embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated. Therefore, the term “the disclosure”, “the present disclosure” or the like does not necessarily limit the claim scope to a specific embodiment, and the reference to particularly preferred exemplary embodiments of the disclosure does not imply a limitation on the disclosure, and no such limitation is to be inferred. The disclosure is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the disclosure. It should be appreciated that variations may be made in the embodiments described by persons skilled in the art without departing from the scope of the present disclosure as defined by the following claims. Moreover, no element and component in the present disclosure is intended to be dedicated to the public regardless of whether the element or component is explicitly recited in the following claims.

What is claimed is:

1. A light source module, comprising:
a substrate;
a light-emitting unit, disposed on the substrate;
a package layer, disposed on the substrate and covering the light-emitting unit, wherein the package layer has a surface facing away from the substrate;
a transparent plate, disposed on the surface and having a first surface and a second surface, wherein the first surface is opposite to the second surface, and the first surface faces away from the package layer; and
an electromagnetic induction layer, disposed on one of the first surface and the second surface.

2. The light source module according to claim 1, wherein the electromagnetic induction layer is disposed on the second surface, and the first surface is formed with a plurality of optical microstructures.

3. The light source module according to claim 1, wherein the light-emitting unit comprises a light-emitting chip, the light-emitting chip is disposed on the substrate, and the package layer covers the light-emitting chip.

4. The light source module according to claim 1, wherein the light-emitting unit comprises a mini light-emitting diode unit or a micro light-emitting diode unit.

5. The light source module according to claim 1, wherein the transparent plate comprises a glass transparent plate, and the first surface and the second surface are located on the glass transparent plate.

6. A display device, comprising:
a light source module, comprising:
a substrate;
a light-emitting unit, disposed on the substrate;
a package layer, disposed on the substrate and covering the light-emitting unit, wherein the package layer has a surface facing away from the substrate;
a transparent plate, disposed on the surface and having a first surface and a second surface, wherein the first surface is opposite to the second surface, and the first surface faces away from the package layer; and
an electromagnetic induction layer, disposed on one of the first surface and the second surface; and
a display panel, disposed on a side of the transparent plate facing away from the package layer.

7. The display device according to claim 6, further comprising an optical film, wherein the electromagnetic induction layer is disposed on the first surface, and the optical film is disposed between the electromagnetic induction layer and the display panel.

8. The display device according to claim 7, further comprising a transparent glue layer, wherein the transparent glue layer is disposed on a side of the electromagnetic induction layer facing away from the transparent plate, and the transparent glue layer is located between the optical film and the electromagnetic induction layer.

9. The display device according to claim 6, wherein the electromagnetic induction layer is disposed on the second surface, and the first surface is formed with a plurality of optical microstructures.

10. The display device according to claim 9, further comprising a solid transparent glue layer, wherein the first surface has a plurality of recessed microstructures to form the plurality of optical microstructures, and the solid transparent glue layer is disposed on the first surface.
